(19) United States
(12) Patent Application Publication
(10) Pub. No.: US 2023/0358809 A1
(43) Pub. Date: Nov. 9, 2023

(54) PERMANENT MAGNET FLUX LINKAGE DETERMINATION FOR PERMANENT MAGNET SYNCHRONOUS MOTORS

(71) Applicants: Shiva GARAEI, Montreal (CA); Chunyan LAI, Montreal (CA); Gerd SCHLAGER, St. Valentin (AT); Lakshmi Varaha IYER, Troy, MI (US); Philip KORTA, Troy, MI (US)

(72) Inventors: Shiva GARAEI, Montreal (CA); Chunyan LAI, Montreal (CA); Gerd SCHLAGER, St. Valentin (AT); Lakshmi Varaha IYER, Troy, MI (US); Philip KORTA, Troy, MI (US)

(21) Appl. No.: 17/911,554

(22) PCT Filed: Mar. 19, 2021
(86) PCT No.: PCT/US2021/023251

§ 371 Date: Sep. 14, 2022

Related U.S. Application Data
(60) Provisional application No. 62/992,179, filed on Mar. 20, 2020.

(51) Int. Cl. G01R 31/34; G01R 19/00; G01R 19/02

(52) U.S. Cl. CPC G01R 31/34; G01R 19/0038; G01R 19/02; H02K 1/276

(57) ABSTRACT

Permanent magnet (PM) flux strength in a permanent magnet synchronous machine (PMSM) can be affected by operating conditions including thermal, mechanical, environmental and electrical stresses. Reduced flux strength, also called demagnetization, can lead to the degradation of the efficiency, performance and reliability of the machine and the drive system. A reliable PM strength, PM flux linkage, PM SOH, PM demagnetization detection method using the same inverter (i.e. motor drive) used to operate the PMSM is provided. The method comprises applying phase voltages to each of a plurality of motor leads of the PMSM with the PMSM at a stand-still condition; measuring current in each of the plurality of motor leads of the PMSM while applying the phase voltages thereto; and determining at least one of flux linkage, PM strength, PM SoH, or PM demagnetization based on a value of the current in at least one of the motor leads.

### CROSS-REFERENCE TO RELATED APPLICATIONS

This PCT International Patent Application claims the benefit of U.S. Provisional Patent Application Ser. No. 62/992,179 filed on Mar. 20, 2020, and titled “Permanent Magnet Flux Linkage Measurement And Estimation Method For High Performance PMSM Control”, the entire disclosure of which is hereby incorporated by reference.

### FIELD

The present disclosure relates generally to the measurement of permanent magnet strength or flux linkage, which can be used towards detection of reversible or irreversible magnetic fault in a permanent magnet synchronous motor (PMSM) and motor control for improved performance. More specifically, the present disclosure relates to a system and method to measure and estimate the state of health (SOH) and strength of a permanent magnet to detect demagnetization within the PMSM in a standstill condition.

### BACKGROUND

Permanent magnet synchronous machines (PMSMs) are widely used in electric vehicles due to their high-power density and high efficiency. Permanent magnet (PM) flux strength in PMSM machines can be affected by operating conditions under thermal, mechanical, environmental and electrical stresses. It can lead to the degradation of the efficiency, performance and reliability of the machine and the whole system. Permanent magnet (PM) demagnetization can result in a severe fault in PMSMs. The PM strength in PMSMs can be affected by their operating conditions under thermal, mechanical, environmental, and electrical stresses or a combination of such stresses. It can lead to unbalanced magnetic pull, reduced torque, degradation of system efficiency and reliability of the overall motor drive system. Demagnetization can cause reduction and distortion of magnetic flux distribution in PMSMs, which can adversely affect fault diagnosis procedures. Demagnetization can result in harmonics and/or degradation in various mechanical and electrical parameters of the motor. PM demagnetization in PMSMs can result from high operating temperature, magnet damage due to aging or/and corrosion, or inappropriate armature current.

### SUMMARY

According to an aspect of the disclosure, a method for monitoring a permanent magnet synchronous machine (PMSM) comprises: applying phase voltages to each of a plurality of motor leads of the PMSM with the PMSM at a stand-still condition; measuring current in each of the plurality of motor leads while applying the phase voltages thereto; and determining at least one of flux linkage, permanent magnet (PM) strength, PM State of Health (SoH), or PM demagnetization based on a value of the current in at least one of the plurality of motor leads.

According to an aspect of the disclosure, a system for monitoring a permanent magnet synchronous machine (PMSM) comprises: an inverter configured to apply phase voltages to each of a plurality of motor leads of the PMSM with the PMSM at a stand-still condition; one or more current sensors configured to measure current in each of the plurality of motor leads while applying the phase voltages thereto; and a controller configured to determine at least one of flux linkage, permanent magnet (PM) strength, PM State of Health, or PM demagnetization of the PMSM based on a value of the current in at least one of the plurality of motor leads.

### BRIEF DESCRIPTION OF THE DRAWINGS

Further details, features and advantages of designs of the invention result from the following description of embodiment examples in reference to the associated drawings.

FIG. 1 shows a block diagram of a system in accordance with the present disclosure;

FIG. 2 shows a cutaway end view of a first PMSM;

FIG. 3 shows a cutaway end view of a second PMSM;

FIG. 4 shows a combination graph including a plot of peak flux vs. current, and a plot of flux vs. inductance;

FIG. 5 shows a graph of applied 3-phase voltages when θ=0°;

FIG. 6 shows a graph of phase A voltage and phase A current when θ=0°;

FIG. 7 shows a graph illustrating variation of phase A root-mean-square current and peak-peak torque with initial position (α) when θ=0°;

FIG. 8 shows a graph with plots comparing torques for α=2° and α=15°, when θ=0°;

FIG. 9 shows a graph with plots of flux linkage of phases A, B, and C when θ=0° and α=15°;

FIG. 10 shows a graph with plots of d-axis current and q-axis current when θ=0° and α=15°;

FIG. 11 shows a graph with plots of d-axis flux and q-axis flux when θ=0° and α=15°;

FIG. 12 shows a graph with plots comparing RMS values of phase A current under healthy and demagnetization conditions;

FIG. 13 shows a graph with plots comparing RMS values of phase B current under healthy and demagnetization conditions;

FIG. 14 shows a graph with plots comparing RMS values of phase C current under healthy and demagnetization conditions;

FIG. 15 shows a graph with plots of % change of RMS phase A current for different demagnetization conditions;

FIG. 16 shows a graph with plots of % change of RMS phase B current for different demagnetization conditions;

FIG. 17 shows a graph with plots of % change of RMS phase B current for different demagnetization conditions;

FIG. 18 shows a graph with plots of apparent inductance vs. d-axis current under healthy and demagnetization conditions;

FIG. 19 shows a graph with plots of incremental inductance vs. d-axis current under healthy and demagnetization conditions;

FIG. 20 shows a graph with plots of phase currents when θ=0° and under healthy conditions;

FIG. 21 shows a graph with plots of torque when θ=0° and under healthy conditions;

FIG. 22 shows a graph with plots of % PM flux reduction vs. % RMS current reduction under two different values of phase resistance;

FIG. 23 shows a graph with a plot of PM flux vs. temperature under healthy conditions; and

FIG. 24 shows a graph with plots of % PM flux reduction vs % RMS reduction for PMSM at three different temperatures.

### DETAILED DESCRIPTION

Referring to the Figures, wherein like numerals indicate corresponding parts throughout the several views, a method and system 10 for detecting permanent magnet (PM) demagnetization in a permanent magnet synchronous machine (PMSM) type electric machine, such as an electric motor, a generator, or a motor/generator. Demagnetization may include weakening of magnetic flux strength produced by one or more permanent magnets in a PMSM. For example, one or more PMs associated with a pole of a PMSM may experience a reduction in produced magnetic flux strength of 10%, which may be characterized as a demagnetization fault.

A new method is provided in this disclosure to diagnose a PM demagnetization fault under the standstill condition using the current. More specifically, voltages are injected into the PMSM under standstill condition using an inverter, and phase currents are measured for analysis to diagnose the local and uniform PM demagnetization faults. Constraints in an electric vehicle (EV) traction system environment are especially considered. In addition to PM demagnetization levels or demagnetization faults, the proposed method may also determine PM flux linkage, PM strength, PM state of health (SOH).

A main goal of the disclosed method and system is to identify PM demagnetization using the same system configuration that is used to operate the electric machine. Namely, the same DC source and inverter used to provide AC power to the electric machine may also be used to identify PM demagnetization of the electric machine. The proposed method is performed under a standstill condition when the rotor speed is zero. This can help to eliminate or reduce temperature variation, load change, noise, mechanical problems such as eccentricity faults, and speed-dependent parameters that can affect a demagnetization fault diagnosis.

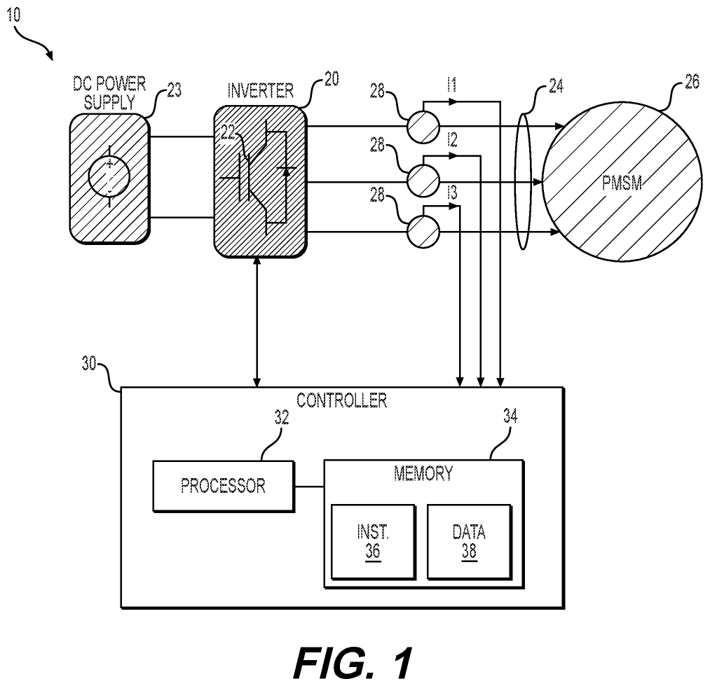

An example of the system 10 is shown in FIG. 1. The system 10 includes an inverter 20, which may also be called a motor drive for its ability to supply alternating current (AC) power to a permanent magnet synchronous machine (PMSM) 26. The inverter 20 includes a plurality of switching transistors 22, which convert DC power from a DC power supply 23 to produce the AC power upon motor leads 24 connected to stator windings of the PMSM 26. The switching transistors 22 may include field effect transistors (FETs), although other devices may be used, such as junction transistors. The DC power supply 23 may include a battery pack in an electrified vehicle (EV) However, the DC power supply 23 may include other devices, such as a rectifier or a generator.

Current sensors 28 monitor phase currents I1, I2, I3 in each of the motor leads 24 and supply detected current values to a controller 30, which is configured to control the operation of the switching transistors 22 of the inverter 20. Additionally or alternatively, the current sensors 28 may be monitored by a different electronic control unit from the controller 30. Any or all of the current sensors 28, may include any known hardware and/or software for sensing electrical current. For example, the current sensors 28, may include any combination of current transformers, shunt resistance, voltage-based and/or current-based sensing, analog-to-digital (A/D) converters, etc.

The controller 30 includes a processor 32, such as a microprocessor or microcontroller, which is in functional communication with a machine-readable storage memory 34. The memory 34 holds program instructions 36 and data 38.

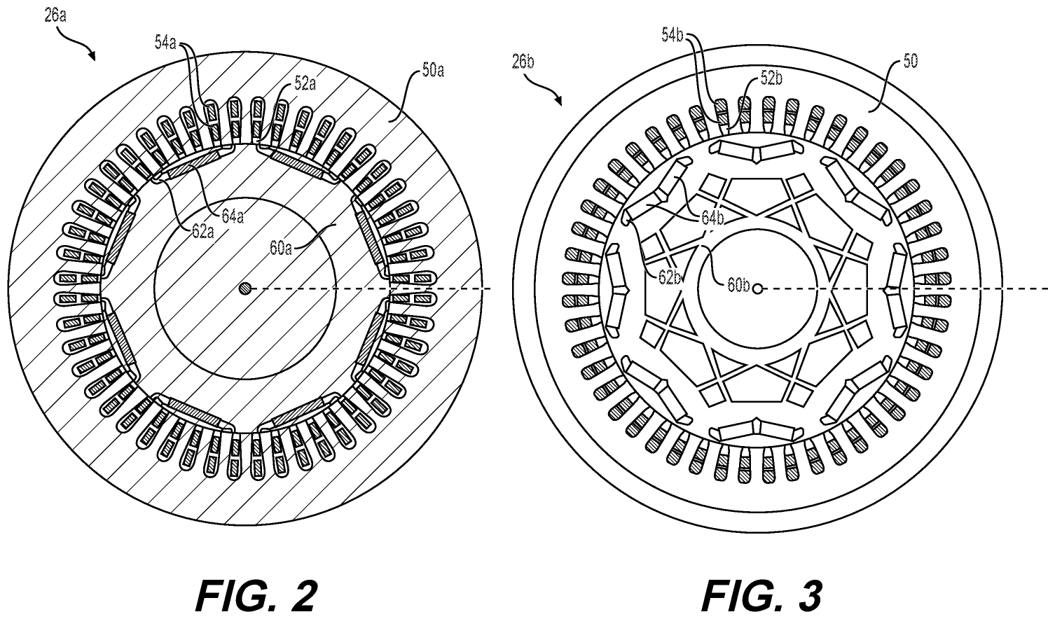

FIG. 2 shows a cutaway end view of a first PMSM 26a, which includes a first stator 50a surrounding a first rotor 60a. The first stator 50a defines a plurality of first slots 52a extending radially inward, spaced at regular intervals, and holding first stator windings 54a, which are connected to corresponding ones of the motor leads 24 to produce a rotating magnetic field. The first stator 60a includes a plurality of flat recesses 62a each extending circumferentially and each holding a first permanent magnet 64a.

FIG. 3 shows a cutaway end view of a second PMSM 26b, which includes a second stator 50b surrounding a second rotor 60b. The second stator 50b defines a plurality of second slots 52b extending radially inward, spaced at regular intervals, and holding second stator windings 54b, which are connected to corresponding ones of the motor leads 24 to produce a rotating magnetic field. The second stator 60b includes a plurality of V-shaped slots 62b each extending radially and circumferentially and each holding a two second permanent magnets 64b.

It should be appreciated the first and second PMSMs 26a, 26b are merely examples, and the system 10 and method of the present disclosure may be used with any PMSM 26 including interior rotor or exterior rotor configurations, and with any number of poles.

The present disclosure provides a current-based method which uses the root mean square (RMS) value of phase stator current to monitor the permanent magnet (PM) health state of the PMSM 26. The technique of the present disclosure may be used to determine any one of several different types of demagnetization faults up to and including demagnetization of all poles within the PMSM 26. Because magnetic flux distribution in a faulty motor is non-uniform, it impacts the motor inductance waveforms. According to the equivalent circuit of the motor, the stator current is affected in this case. Indeed, by comparing the current waveforms and their properties for both healthy and faulty motors, a fault can be detected and classified. Equivalent inductance variations with magnetic saturation depend on the relative position between the stator and rotor magnetic fields.

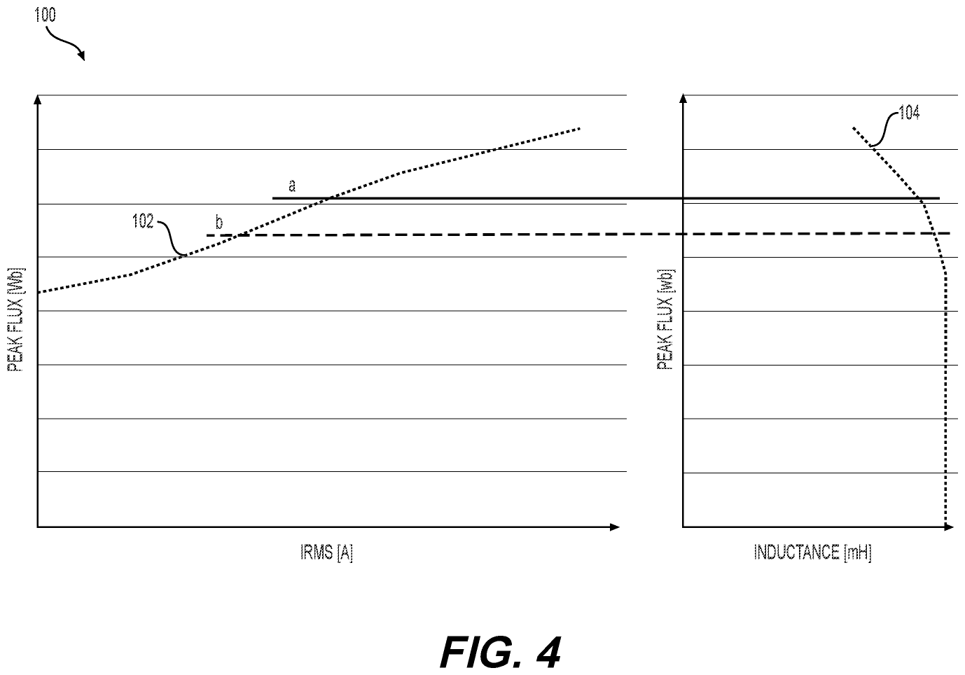

As a result of demagnetization, the magnet flux decreases, and the operating point is shifted down in the flux-current curve. FIG. 4 shows a combination graph 100 including a plot 102 of flux φ vs. current i, and a plot 104 of flux φ vs. inductance L. As shown in FIG. 4, the operating point a (healthy machine) shifts down to operating point b, due to the demagnetization. That means the core magnetic material is less saturated and the value of inductance is higher which leads to a reduction of current passing through the windings. The proposed method uses the RMS value of the stator phase current and compares it with the same value for the healthy motor.

A demagnetization index k_{d} is defined for demagnetization fault detection. The demagnetization index k_{d} represents a relative change (%) of RMS value of phase current in the faulty machine against a healthy machine. The severity of a demagnetization fault is indicated by this index k_{d}. The demagnetization index k_{d} may be calculated by the following equation (1):

$${k}_{d} = \frac{{I}_{rms ( faulty )} - {I}_{rms ( healthy )}}{{I}_{rms ( healthy )}} \times 100 \% \qquad ( 1 )$$

where I_{rms(healthy)} and I_{rms(faulty)} are the RMS values of phase currents when the PMSM 26 is healthy and faulty, respectively.

In the proposed method a phase voltage set applied using an inverter 20, to excite the PMSM 26 as shown in equation (2), below:

vₐₛ^{*}(θ, ωt)=Vₘ·cos (θ)·sin (ωt)

v_{bs}^{*}(θ, ωt)=Vₘ·cos (θ−2π/3)·sin (ωt)

v_{cs}^{*}(θ, ωt)=Vₘ·cos (θ−2π/3)·sin (ωt) (2)

where Vₘ, ω and θ are voltage amplitude, excitation frequency, and flux vector angle, respectively, flux vector angle (θ) can change from 0° to 180°.

The inverter 20 may be controlled to generate a sinewave or space vector PWM to generate the three-phase voltages. Amplitude and frequency of the injected voltages are calculated based on motor's equivalent circuit parameters such as stator resistance and inductances to achieve the desired current amplitude that guarantees that the motor is saturated. The resultant magnetic flux in the motor pulsates between two points, θ and θ+180°. Due to this magnetic flux, the electromagnetic torque induced by the stator at θ and θ+180° would have the same amplitude and opposite direction which leads to zero average torque. Thus, the speed of the rotor remains zero.

An 8-pole internal-rotor PMSM (IPMSM) 26a, shown on FIG. 2, is modelled in Ansys Maxwell FEA software. The rotor and stator core of the IPMSM 26a is made of M19 G29 silicon steel. The magnet of IPMSM 26a is NdFeB 35. Parameters of the IPMSM 26a used in the simulation are given in Table 1, below.

TABLE 1
Rating and parameters
of simulated motor

| | | |
|---|---|---|
| Maximum Speed | 1500 | RPM |
| Rated Line Voltage | 275 | V |
| Rated Phase Current | 120 | Aᵣₘₛ |
| d-axis Inductance | 1.021 | mH |
| q-axis Inductance | 1.902 | mH |
| Stator Resistance | 0.024 | Ω |

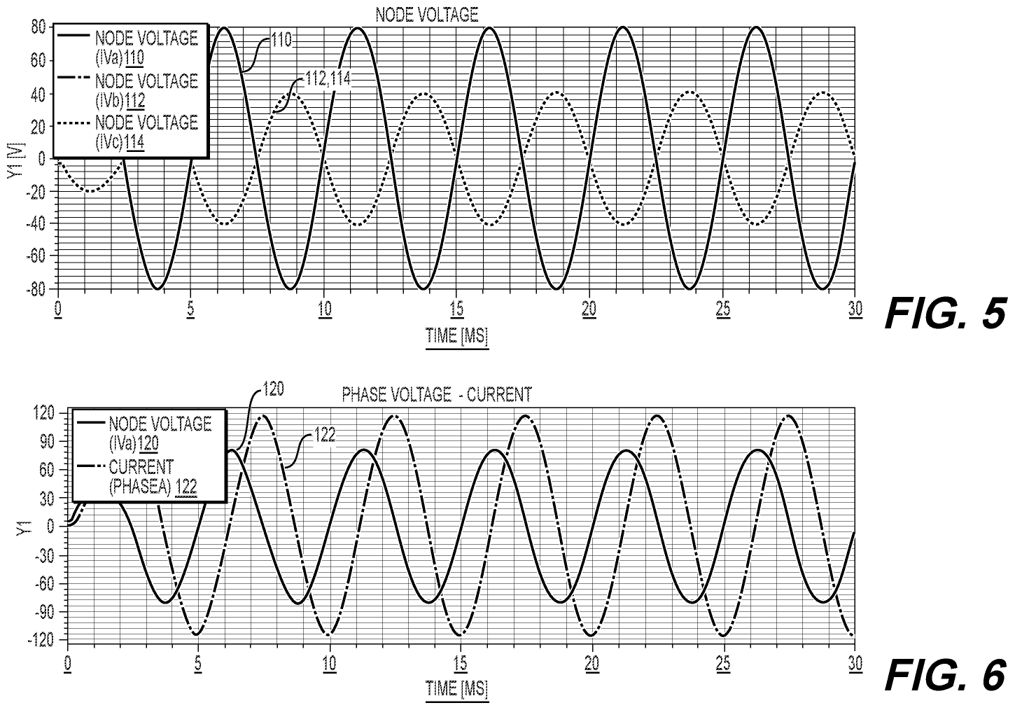

In the simulation Vₘ is 80 V, ω is equal to 2π×200 radians/second, and θ is varied from 0° to 180° in 30° steps. Selecting these values guarantee the core saturation. With these values, the demagnetization indicator is large enough to diagnose different levels of fault. The results of a simulation for one case (when θ=0°) is shown in FIGS. 5-6. Specifically, FIG. 5 shows a graph with plots of A, B, and C node voltages 110, 112, 114, respectively. FIG. 6 shows a graph with a plot 120 of node A voltage and a plot 122 of phase A current. The waveform of injected voltages signal and the stator phase current are as following: Both signal sets are sinusoidal. In this specific case phase B and C have same magnitude and phase, as indicated by the overlapping plots 112, 114 on FIG. 5.

### Determination of Flux Vector Angle for Minimum Torque Oscillation

Another input in simulations is initial position. For a random initial position, proper flux vector angle selection is important to eliminate torque oscillation problems during testing. For this purpose, torque peak to peak value is measured at different initial positions to get the minimum torque ripple.

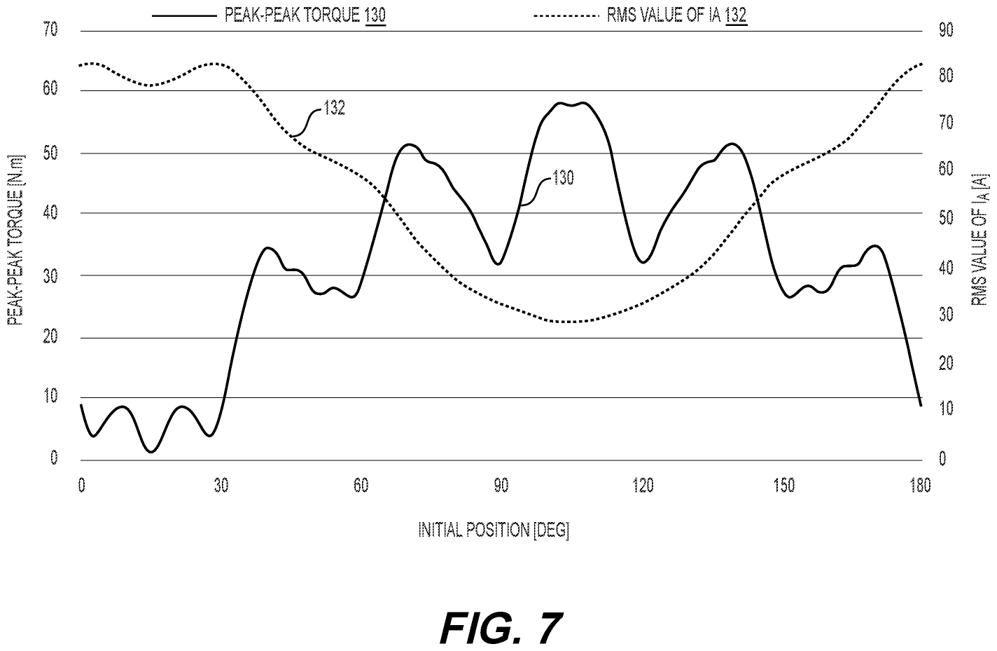

As the proposed fault detection method is designed for stand-still condition of the motor, an oscillating torque is resulted from the injected currents, which could cause noise and vibration during the test. The peak-peak value of the torque can be minimized by selecting a proper flux vector angle (θ) or an initial position (α). When the initial position α is fixed at a specific angle, selection of proper flux vector angle θ is important because it not only affects the peak-peak torque but also has an effect on RMS value of the phase current. It is important to understand this effect, as RMS value of the stator current is used to calculate PM strength in the proposed method. Similarly, for a fixed flux vector angle θ, changing the initial position α affects peak-peak torque and RMS value of the phase current. In most applications, the motor initial position α is fixed, but in this investigation the flux vector angle θ is fixed. Details are explained as: to investigate the impact of initial position α for a flux vector angle θ, a sweep test on initial position α is conducted for half the electrical cycle. FIG. 7 shows a graph with a plot 130 peak-peak torque developed by the IPMSM 26a and a plot 132 of root-mean-square (RMS) phase-A current I_{A_rms}, each as a function of initial position α (degrees) for the healthy motor, when flux vector angle θ=0°. It is evident that the peak-peak torque is near zero when initial position α=15°. As this first PMSM 26a works in the stand-still condition, the initial position of the rotor affects the inductance for each phase, and as a result, the stator current is different at different initial positions.

Simulations were performed with different initial positions for each flux vector angle θ to obtain a mechanical angle at which the produced torque is close to zero. It can be seen from FIG. 7 how initial position has effect on phase current I_{A_rms} because of inductance changes. Moreover, the reluctance component of the induced torque changes as the rotor position changes.

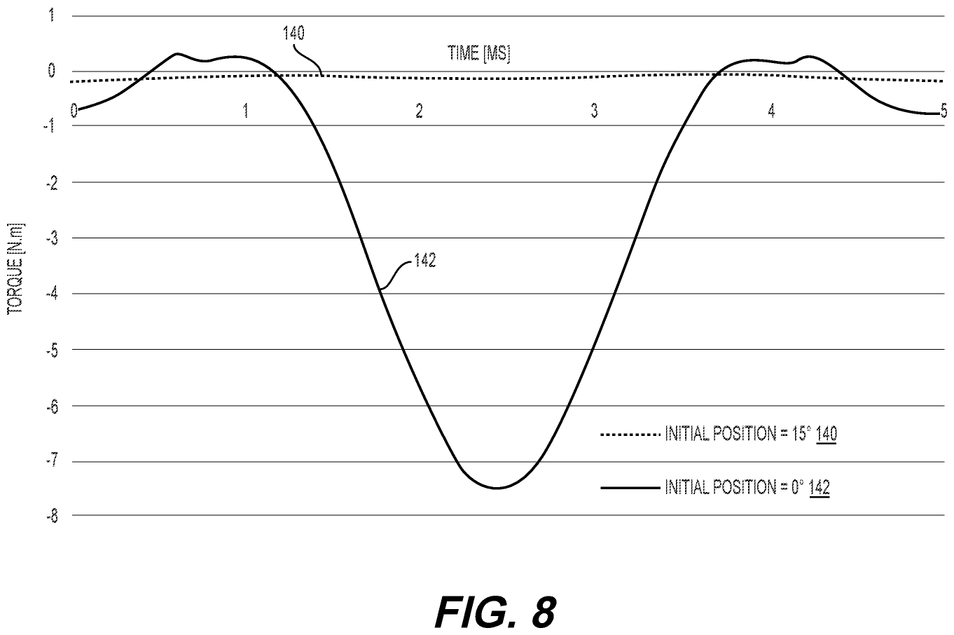

FIG. 8 shows a graph with plots 140, 142 of torque when flux vector angle θ=0° for initial position α=0°, and α=15°, respectively. FIG. 8 compares the torque waveforms of a healthy IPMSM with a constant supply voltage at two different initial positions when flux vector angle θ=0°. By using the initial position of 15°, the PMSM 26 produces near zero torque.

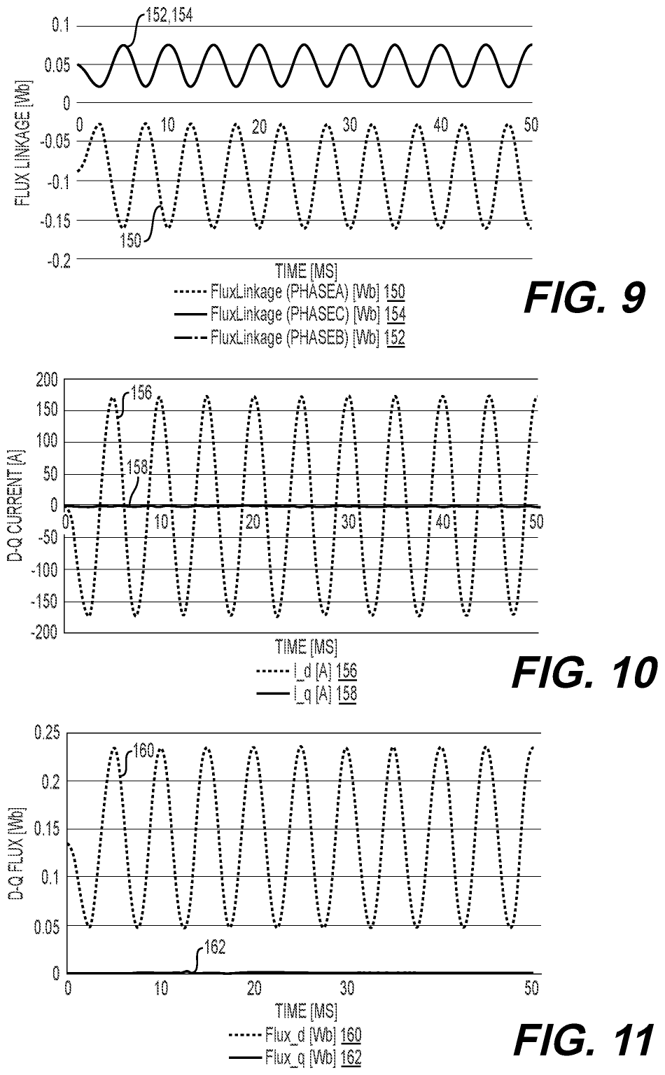

FIG. 9 shows a graph with plots 150, 152, 154 of flux linkage of phases A, B, and C, respectively. FIG. 10 shows a graph with plots 156, 158 of d-axis current I_{d} (Amps) and q-axis current I_{q} (Amps), respectively. FIG. 11 shows a graph with plots 160, 162 of d-axis flux (Webers) and q-axis flux (Webers), respectively. Together, FIGS. 9-11 show how a,b,c fluxes, d-q fluxes, and current behave with a proper initial position α of the rotor 60a, 60b that causes the PMSM 26 to develop zero torque. The initial position α of the rotor 60a, 60b is selected such that both the q-axis current and flux linkage are near zero. So, at this position only the d-axis current and flux linkage are presented. As a result, the instantaneous/peak-peak and average values of the developed electromagnetic torque are close to zero, based on the relationship described in equation (3), below.

$$T = \frac{3}{2} P \times [ {i}_{q} . {λ}_{d} - {i}_{d} . {λ}_{q} ] \qquad ( 3 )$$

### Impact of Flux Vector Angle on Stator Phase Current

To study the RMS value of the phase current, the flux vector angle has been varied from 0° to 360° with a 30° step. For each flux vector angle, a proper initial position angle was selected to keep the torque peak to peak value at minimum. In this section all the simulation results are for IPMSM with Vₘ=80 V, ω is equal to 2π×200, and with the proper initial position selected to keep the torque peak to peak value at minimum.

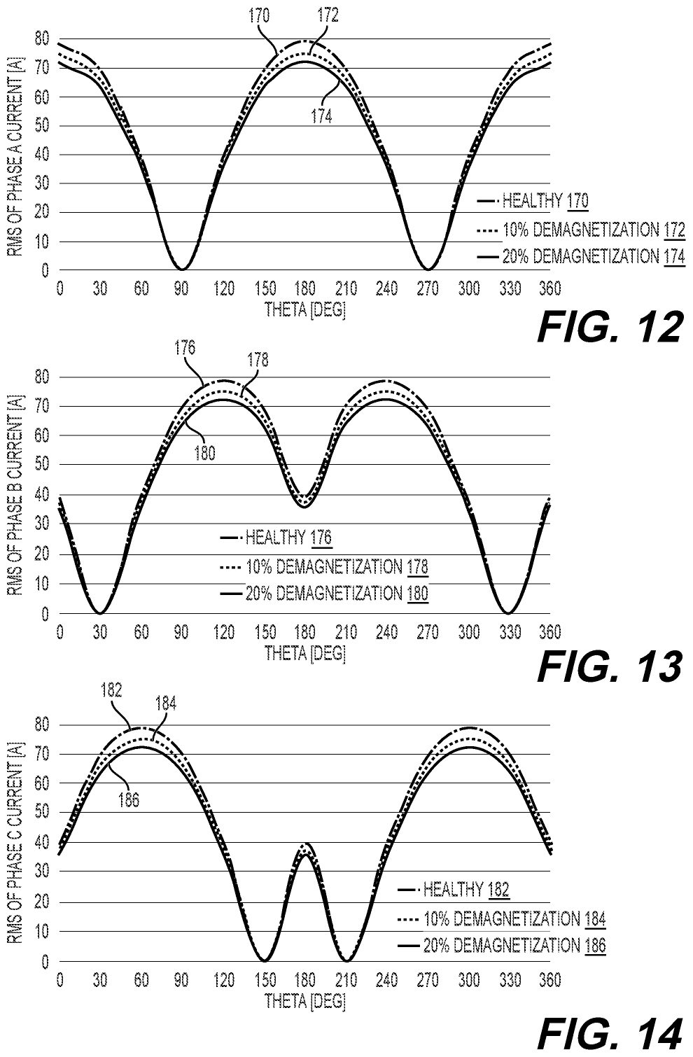

FIG. 12 shows a graph with plots 170, 172, 174 comparing RMS values of phase A current (Amps) as a function of flux vector angle (Theta (θ)) under healthy, 10% demagnetization condition, and 20% demagnetization condition, respectively. FIG. 13 shows a graph with plots 176, 178, 180 comparing RMS values of phase B current (Amps) as a function of flux vector angle (Theta (θ)) under healthy, 10% demagnetization condition, and 20% demagnetization condition, respectively. FIG. 14 shows a graph with plots 182, 184, 186 comparing RMS values of phase C current (Amps) as a function of flux vector angle (Theta (θ)) under healthy, 10% demagnetization condition, and 20% demagnetization condition, respectively. Together, FIGS. 12-14 show simulation results of the RMS of phase A, B and C current in healthy and faulty conditions for the IPMSM 26a. RMS of phase current under healthy and faulty conditions follow the same pattern for all three phases. As it is expected, increasing the level of demagnetization for leads to lower RMS values as a result of larger inductance. According to the simulation results, the RMS value between 180° to 360° is same as the value between 0° to 180°, that makes simulation and test easier. Also, the fault indicator variation for different flux vector angle is small.

Three cases are analyzed to observe the motor behavior under demagnetization condition and changes in the demagnetization indicator: healthy motor, 10% and 20% uniform demagnetized motor. In uniform demagnetization all eight poles have been demagnetized with the same level of demagnetization. In this report the RMS value of stator phase current is used to calculate the fault indicator as in equation (1), and the impact of demagnetization is investigated.

The following tables 2, 3 and 4 show results obtained from simulation that are used to drawing comparison between different conditions.

TABLE 2
Results of healthy motor with selected initial position

| | Electrical | | | | | |
|---|---|---|---|---|---|---|
| | Initial | Torque | Torque | | | |
| Theta | Position | pk2pk | avg | RMS(A) | RMS(B) | RMS(C) |
| [deg] | [deg] | [N · m] | [N · m] | [A] | [A] | [A] |
| 0 | 15 | 0.09 | −0.09 | 78.58 | 39.29 | 39.29 |
| 30 | 45 | 0.23 | −0.05 | 69.53 | 0.02 | 69.54 |
| 60 | 75 | 0.09 | −0.09 | 39.29 | 37.29 | 78.58 |
| 90 | 105 | 0.23 | −0.05 | 0.019 | 69.54 | 69.53 |
| 120 | 135 | 0.09 | −0.09 | 39.29 | 78.58 | 39.29 |
| 150 | 165 | 0.23 | −0.05 | 69.54 | 69.53 | 0.02 |
| 180 | 15 | 0.09 | −0.09 | 78.53 | 39.27 | 39.26 |

TABLE 3
Results of 10% demagnetized motor with selected initial position

| | Electrical | | | | | |
|---|---|---|---|---|---|---|
| | Initial | Torque | Torque | | | |
| Theta | Position | pk2pk | avg | RMS(A) | RMS(B) | RMS(C) |
| [deg] | [deg] | [N · m] | [N · m] | [A] | [A] | [A] |
| 0 | 15 | 0.05 | −0.06 | 75.08 | 37.55 | 37.53 |
| 30 | 45 | 0.08 | −0.06 | 66.26 | 0.02 | 66.26 |
| 60 | 75 | 0.05 | −0.06 | 37.54 | 37.53 | 75.07 |
| 90 | 105 | 0.08 | −0.05 | 0.023 | 66.26 | 66.26 |
| 120 | 135 | 0.05 | −0.06 | 37.53 | 75.08 | 37.55 |
| 150 | 165 | 0.08 | −0.05 | 66.27 | 66.27 | 0.02 |
| 180 | 15 | 0.05 | −0.06 | 75.08 | 37.55 | 37.53 |

TABLE 4
Results of 20% demagnetized motor with selected initial position

| | Electrical | | | | | |
|---|---|---|---|---|---|---|
| | Initial | Torque | Torque | | | |
| Theta | Position | pk2pk | avg | RMS(A) | RMS(B) | RMS(C) |
| [deg] | [deg] | [N · m] | [N · m] | [A] | [A] | [A] |
| 0 | 15 | 0.03 | −0.04 | 72.24 | 36.14 | 36.10 |
| 30 | 45 | 0.06 | −0.06 | 63.72 | 0.02 | 63.72 |
| 60 | 75 | 0.03 | −0.04 | 36.13 | 36.10 | 72.23 |
| 90 | 105 | 0.06 | −0.06 | 0.02 | 63.72 | 63.72 |
| 120 | 135 | 0.03 | −0.04 | 36.10 | 72.24 | 36.14 |
| 150 | 165 | 0.06 | −0.06 | 63.73 | 63.72 | 0.02 |
| 180 | 15 | 0.03 | −0.04 | 72.24 | 36.14 | 36.10 |

Comparisons between RMS values of stator current for phases A, B and C under healthy and demagnetization conditions are listed in table 5, below and are shown on FIGS. 12-14.

TABLE 5
RMS value of phase currents of IPMSM

| | Phase A | | |
|---|---|---|---|
| | | 10% | 20% |
| Theta | Healthy | Demag | Demag |
| 0 | 78.58 | 75.08 | 72.24 |
| 30 | 69.53 | 66.26 | 63.72 |
| 60 | 39.29 | 37.54 | 36.13 |
| 90 | 0.019 | 0.023 | 0.02 |
| 120 | 39.29 | 37.53 | 36.10 |
| 150 | 69.54 | 66.27 | 63.72 |
| 180 | 78.53 | 75.08 | 72.24 |
| | Phase B | | |
| | | 10% | 20% |
| Theta | Healthy | Demag | Demag |
| 0 | 39.29 | 37.55 | 36.14 |
| 30 | 0.02 | 0.02 | 0.02 |
| 60 | 39.29 | 37.53 | 36.10 |
| 90 | 69.54 | 66.26 | 63.72 |
| 120 | 78.58 | 75.08 | 72.24 |
| 150 | 69.53 | 66.27 | 63.72 |
| 180 | 39.27 | 37.55 | 36.14 |
| | Phase C | | |
| | | 10% | 20% |
| Theta | Healthy | Demag | Demag |
| 0 | 39.29 | 37.53 | 36.10 |
| 30 | 69.54 | 66.26 | 63.72 |
| 60 | 78.58 | 75.07 | 72.23 |
| 90 | 69.53 | 66.263 | 63.72 |
| 120 | 39.29 | 37.55 | 36.14 |
| 150 | 0.02 | 0.02 | 0.02 |
| 180 | 39.27 | 37.53 | 36.10 |

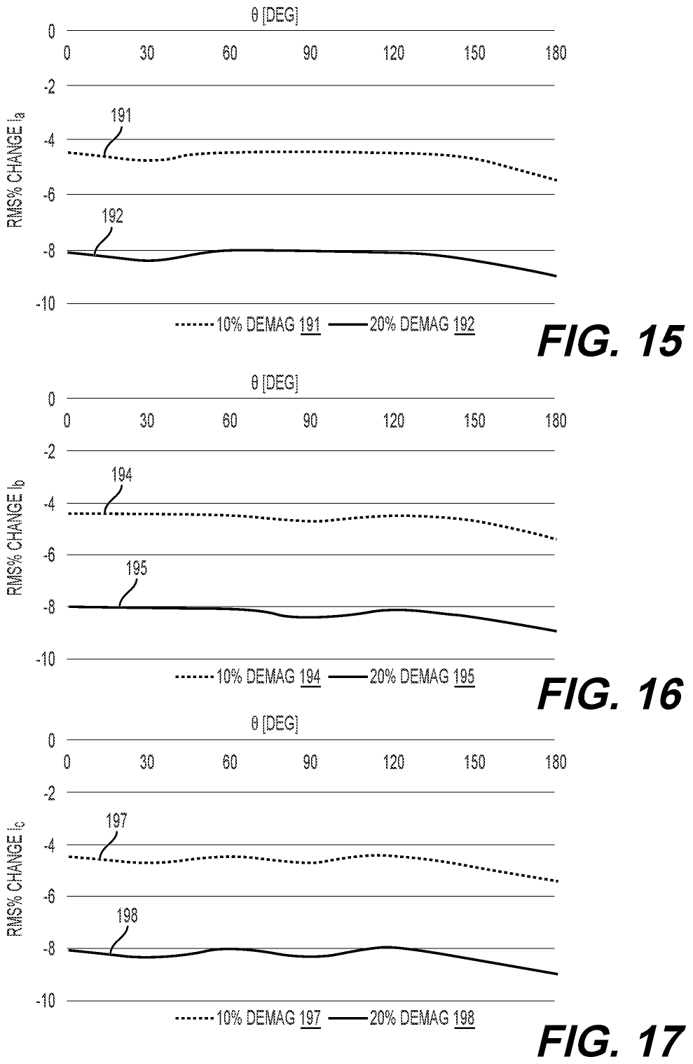

The values of the fault indicator K_{d} for three phases under faulty conditions are presented in Table 6 and are shown on FIGS. 15-17.

TABLE 6
The value of K_{d} for phase
A, B and C of IPMSM with
selected initial position

| | Phase A | |
|---|---|---|
| | 10% | 20% |
| Theta | Demag | Demag |
| 0 | 4.5 | 8.1 |
| 30 | 4.7 | 8.4 |
| 60 | 4.4 | 8.0 |
| 90 | — | — |
| 120 | 4.5 | 8.1 |
| 150 | 4.7 | 8.4 |
| 180 | 4.4 | 8.0 |
| | Phase B | |
| | 10% | 20% |
| Theta | Demag | Demag |
| 0 | 4.4 | 8.0 |
| 30 | — | — |
| 60 | 4.5 | 8.1 |
| 90 | 4.7 | 8.4 |
| 120 | 4.5 | 8.1 |
| 150 | 4.7 | 8.4 |
| 180 | 4.4 | 8.0 |
| | Phase C | |
| | 10% | 20% |
| Theta | Demag | Demag |
| 0 | 4.5 | 8.1 |
| 30 | 4.7 | 8.4 |
| 60 | 4.5 | 8.1 |
| 90 | 4.7 | 8.4 |
| 120 | 4.4 | 8.0 |
| 150 | — | — |
| 180 | 4.4 | 8.0 |

### Fault Classification

Demagnetization faults can be categorized as uniform or partial. In uniform demagnetization, all the magnets are demagnetized to the same level uniformly. Any demagnetization other than the uniform case can be called non-uniform or partial demagnetization. The demagnetization fault diagnosis using the fault indicator addressed in the previous section and the demagnetization fault classification is discussed in this section. As the demagnetization affects the magnetic flux linkage of the motor, any trace of this fault and uniformity or nonuniformity of that is clear in the magnetic flux. The d-axis flux λ_{d} can be estimated by equation (4):

λ_{d}=λₘ+L_{d}*i_{d} (4)

where λₘ and L_{d} are the PM flux linkage and d-axis inductance, respectively. So, d-axis inductance L_{d} which is named “apparent” d-axis inductance is given in equation (5):

$${L}_{d} = \frac{{λ}_{d} - {λ}_{m}}{{i}_{d}} \qquad ( 5 )$$

where L_{d} is the slope of λ_{d}−i_{d} characteristics and shows that how the magnetic flux changes with the current in d-axis. It can be used to capture the variation of magnetic flux in the case of demagnetization fault. Direct axis (d-axis) differential inductance (L′_{d}) is defined by equation (6):

$${L}_{d}^{′} = \frac{d {λ}_{d}}{{di}_{d}} \qquad ( 6 )$$

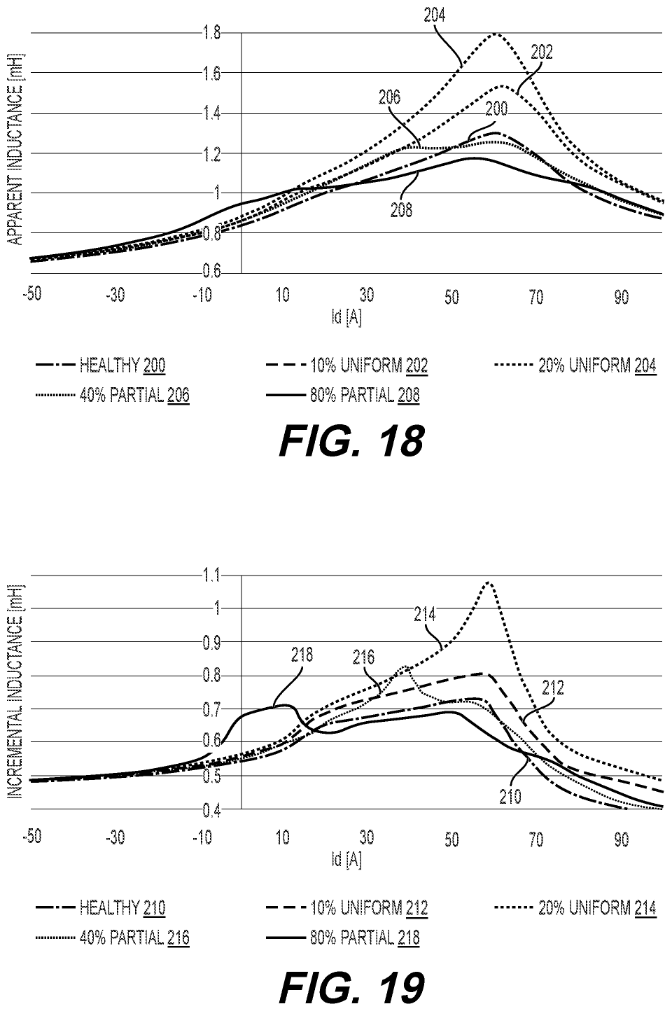

Uniform and partial demagnetized cases with the same overall demagnetization ratio are compared. FIGS. 18-19 show the L_{d}−i_{d} and L′_{d}−i_{d} characteristic for a PMSM 26 with healthy, uniform, and partial faulty conditions. FIG. 18 shows a graph with plots 200, 202, 204, 206, 208 of apparent inductance (mH) vs. d-axis current (Amps) under healthy and demagnetization conditions. Specifically, plot 200 shows apparent inductance vs. d-axis current for a PMSM 26 with healthy condition; plot 202 shows apparent inductance vs. d-axis current for a PMSM 26 with uniform 10% demagnetization; plot 204 shows apparent inductance vs. d-axis current for a PMSM 26 with uniform 20% demagnetization; plot 206 shows apparent inductance vs. d-axis current for a PMSM 26 with partial 40% demagnetization; and plot 208 shows apparent inductance vs. d-axis current for a PMSM 26 with partial 80% demagnetization. FIG. 19 shows a graph with plots 210, 212, 214, 216, 218 of incremental inductance (mH) vs. d-axis current (Amps) under healthy and demagnetization conditions. Specifically, plot 210 shows incremental inductance vs. d-axis current for a PMSM 26 with healthy condition; plot 212 shows incremental inductance vs. d-axis current for a PMSM 26 with uniform 10% demagnetization; plot 214 shows incremental inductance vs. d-axis current for a PMSM 26 with uniform 20% demagnetization; plot 216 shows incremental inductance vs. d-axis current for a PMSM 26 with partial 40% demagnetization; and plot 218 shows incremental inductance vs. d-axis current for a PMSM 26 with partial 80% demagnetization. As expected, the apparent inductance is less sensitive to variation of d-axis current. So, incremental inductance is chosen to classify demagnetization type.

As clear from FIGS. 18-19, by increasing the level of partial demagnetization the peak of curve shifts to left. The asymmetry of the magnetic flux because of the partial demagnetization results in a different L_{d}−i_{d} and L′_{d}−i_{d} pattern. In the case of partial demagnetization, the peak point of the curve shifts to the left. However, uniform demagnetization fault follows the pattern of a healthy case.

### Summary

The first step in the proposed fault diagnosis method is finding RMS values of phase current for a healthy PMSM, and storing those RMS phase currents as reference values. RMS value of phase currents in a PMSM to be evaluated may then be compared with those reference values.

Based on the obtained results, each phase can be evaluated during a test. It should be noted that fault indicator just shows the severity of demagnetization not the exact percentage of demagnetization.

From Tables 6, it can be seen that by selecting the best initial position when the IPMSM is 10% demagnetized the k_{d} is changing 4.4%-4.7% and for 20% demagnetized motor, k_{d} is varying between 8%-8.4%. Moreover:
It can be concluded just one test for a single flux vector angle θ is needed to diagnose the fault, since the indicator value does not have sharp change for different flux vector angles θ.
It should be noted that the flux vector angles at which the current is zero should not be selected to excite the motor for fault detection. For example, flux vector angle θ=90° in phase A, θ=30° in phase B and θ=150° in phase C.
The only consideration is keeping the same condition for test, DC-bus voltage, frequency of PWM carrier, injected voltage and the initial position.
In L_{d}−i_{d} and L′_{d}−i_{d} curve, properties of peak point in healthy case is selected as reference. In uniform fault, pattern is the same with healthy case and peak point happens at higher I_{d}. In non-uniform fault, pattern is different from healthy case and peak point happens at lower I_{d}.

### Simulation Results for Second PMSM 26b

In this section simulation is repeated for a PMSM 26 having the second PMSM 26b configuration, shown in FIG. 3. The proposed method is designed for stand-still condition of the PMSM 26. It is shown that the peak-peak value of the torque can be minimized by selecting a proper flux vector angle θ or an initial rotor position α. Besides, changing the flux vector angle θ or the initial position α affects the peak-peak torque and affects the RMS value of the phase current.

The relationship between flux vector angle θ and initial position α can be extracted for all motors as equation (7):

$$θ = \{ \begin{matrix}α + δ & if α + δ < 180 ° \\ α + δ - 180 ° & if α + δ \geq 180 °\end{matrix} \qquad ( 7 )$$

where δ can be defined based on equation (8):

$$δ = ( \frac{180}{Number of Slots} ) * \frac{P}{2} \qquad ( 8 )$$

where P is the number of poles in the rotor of the PMSM 26.

The desired flux vector angle θ can be calculated using equation (7) to ensure the peak-peak torque is close to zero at any random initial position. The initial rotor position is set to such a position that the d-axis flux is aligned with phase A flux. As a result, both the q-axis current and flux linkage are close to zero, and consequently, the developed electromagnetic torque in this condition is approximately equal to zero.

A conventional 3-phase IGBT inverter 20 is also modeled using Ansys Simplorer, and co-simulation is conducted to operate the motors 26a, 26b with the inverter 20. A sinewave or space vector PWM can be used to generate the three-phase voltages.

In a simulation study, the DC bus voltage was set to 100 V. However, the DC bus voltage can be set to a value of V_{DC} that is higher than 100 V. Vₘ is calculated using equation (9):

$${V}_{m} = \frac{2}{3} * ma * {V}_{DC} \qquad ( 9 )$$

where ma is the modulation index. In the simulation, ma is 1, but it can be set to some other values to get Vₘ=66.7 V and ω is equal to 2π×200 rad/second. With these values, the demagnetization indicator is large enough to diagnose different levels of fault. The second PMSM 26b has 48 slots, so equation (8) can be refined as equation (10), below:

$$δ = ( \frac{180 °}{48} ) \times \frac{8}{2} = 15 ° \qquad ( 10 )$$

In the simulation, the initial position α is 165°, so according to equation (7), the flux vector angle θ is 0°.

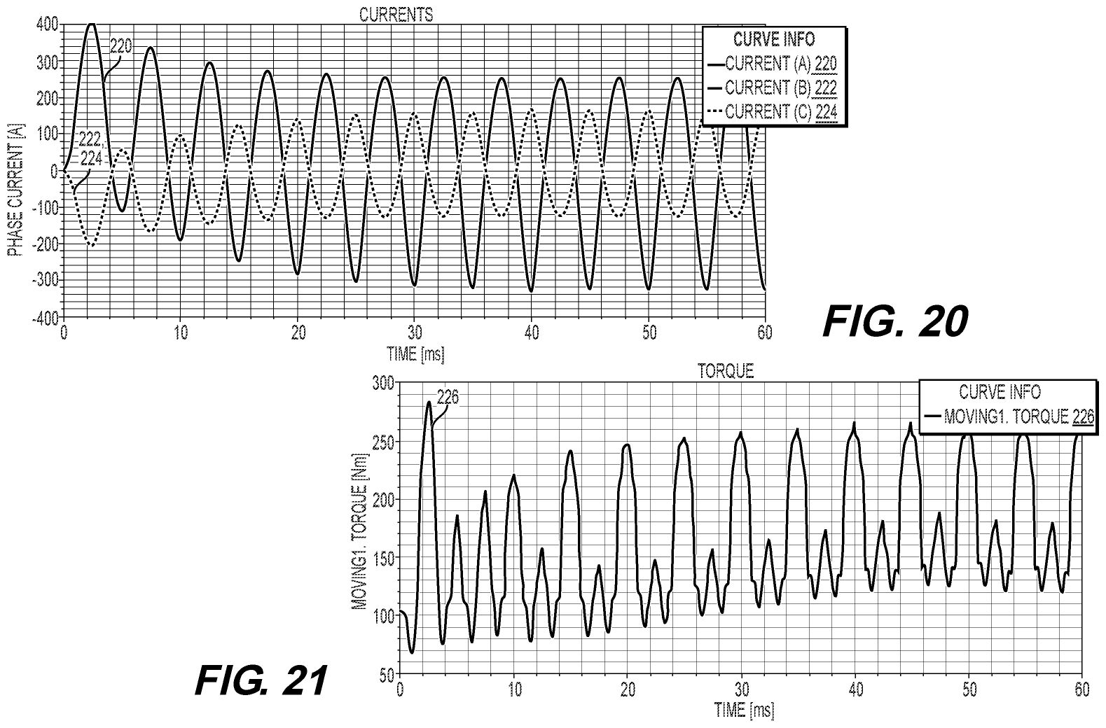

Plots of Currents and torque for the second PMSM 26b under healthy conditions are shown in FIGS. 20-21. FIG. 20 shows a graph with plots 220, 222, 224 of phase currents (Amps) when the flux vector angle θ=0° and under healthy conditions. Specifically, plot 220 shows phase A current; plot 222 shows phase B current, and plot 224 shows phase C current. FIG. 21 shows a graph with a plot 226 torque (Newton-meters) when flux vector angle θ=0° and under healthy conditions.

A uniform demagnetization fault is simulated in the simulation. The main feature of the uniform demagnetization is that all the magnets 64b are demagnetized uniformly, which causes a uniform decrease in the overall magnetic flux linkage in the second PMSM 26b.

### Impact of Stator Phase Resistance on PM Strength

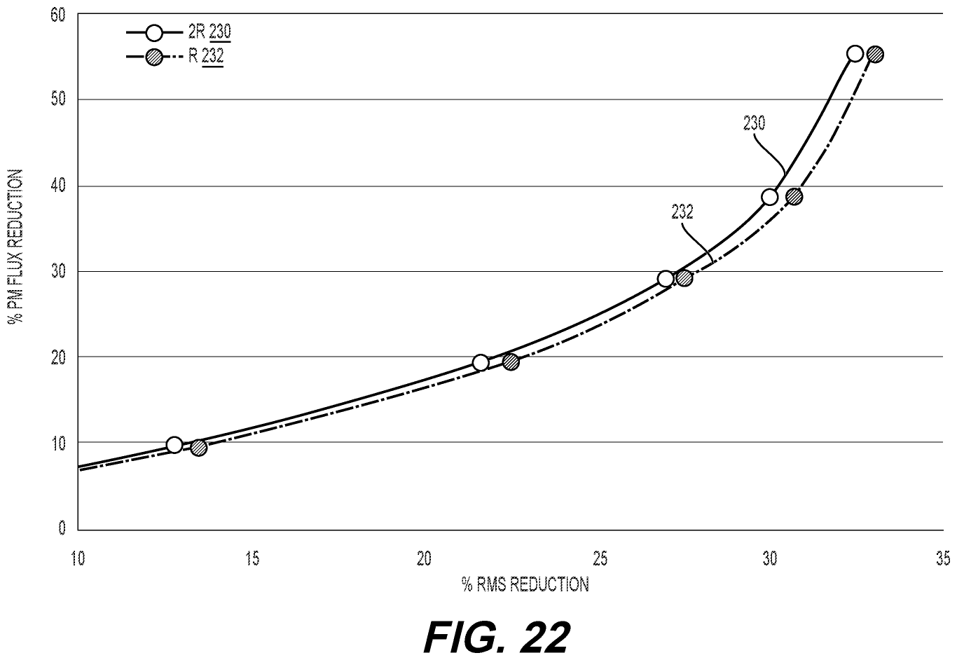

Phase resistance value is doubled to investigate the impact of resistance variation on PM flux strength determination. Temperature of magnet and winding are kept constant at 22° C. during simulations. Then the magnet is demagnetized by reducing the PM strength step by step to see the change in RMS value of phase current. FIG. 22 includes a graph with plots 230, 232 showing results of the simulation. Plot 230 shows % PM flux reduction vs % RMS current reduction for a first value of phase resistance of 2R. Plot 232 shows % PM flux reduction vs % RMS current reduction for a second value of phase resistance of R, which is one-half the first value of phase resistance. As it can be seen, in low level of demagnetization, the difference between both graphs is negligible. However, the difference is more apparent in more severe cases of demagnetization.

### Impact of Temperature on PM Strength

Demagnetization of permanent magnet material can be due to temperature rise. This is mainly related to the temperature coefficient of the permanent magnet material. Temperature affects magnetism by either strengthening or weakening a magnet's attractive force. A magnet subjected to heat experiences a reduction in its magnetic field as the particles within the magnet are moving at an increasingly faster and more sporadic rate. Increasing temperature affects both the stator resistance and magnets strength. In the following subsection, the impact of stator phase resistance change and then the impact of temperature on PM flux reduction and phase A current's RMS value is discussed.

Simulations were performed to analyze the effect of temperature on the RMS value of phase current. In the first step, temperature swept from 22° C. to 120° C. with 20° C. steps, and PM strength is calculated using the no-load test. It should be noted that in each set of simulation, phase resistance is adopted with temperature using equation (12), below:

R=R_{ref}[1+0.00393(T−T_{ref})] (12)

where T is conductor temperature in degrees Celsius, T_{ref} is reference temperature, R is conductor resistance at temperature T, R_{ref} is conductor resistance at reference temperature.

Table 7, below, shows the relationship between PM flux strength and temperature is almost linear.

TABLE 7
PM flux value under healthy condition with different temperatures

| | | | | % Reduction |
|---|---|---|---|---|
| | Temper- | RMS | PM Flux (Wb) | in PM Flux |
| | ature | of Phase A | Resultant of no- | Resultant |
| | (° C.) | Current (A) | load test | of no-load test |
| Healthy | 22 | 191.46 | 0.020033 | — |
| Healthy | 20 | | 0.019591 | — |
| Healthy | 40 | 176.83 | 0.019114368 | 2.43 |
| Healthy | 60 | 169.66 | 0.018625002 | 4.93 |
| Healthy | 80 | 163.41 | 0.018123 | 7.49 |
| Healthy | 100 | 153.64 | 0.01761 | 10.11 |
| Healthy | 120 | 152.92 | 0.017087 | 12.78 |

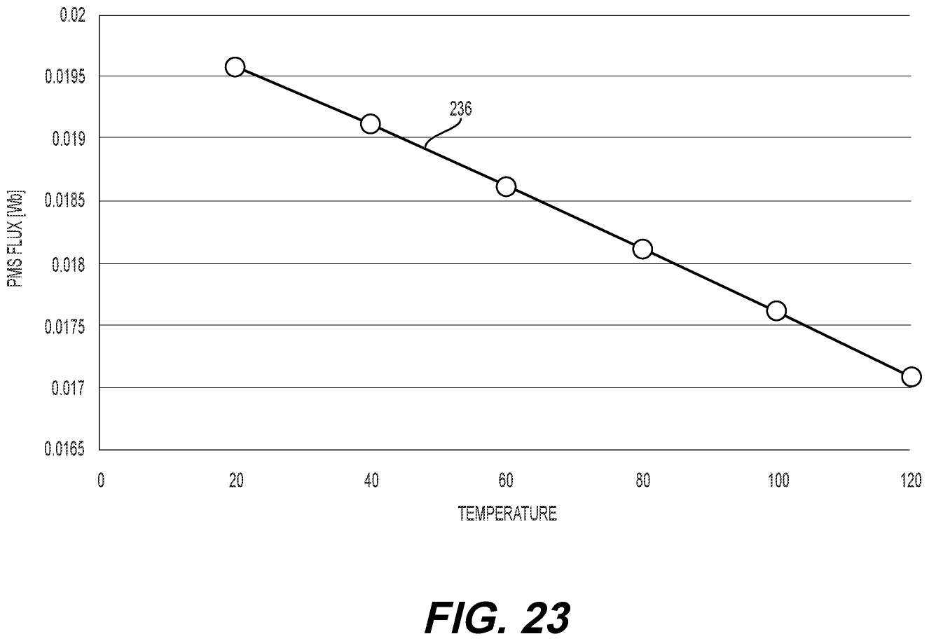

This relationship is plotted in FIG. 23, which shows a plot 236 of PM flux strength (Webers) vs temperature (degrees C.).

In the next step, a faulty motor with different demagnetization severity at 22° C., 80° C. and 120° C. temperatures is modeled.

TABLE 8
Rₚₕₐₛₑ = 16.3749 mOhm, Magnet and Winding Temperature = 22° C.

| | | RMS of | | | % Reduction | |
|---|---|---|---|---|---|---|
| | | Phase A | % Reduction | PM Flux (Wb) | in PM Flux | Torque |
| | | Current | in RMS value | Resultant of | Resultant of | pk2pk |
| no | | (A) | of Phase A | no-load test | no-load test | (mN · m) |
| 1 | Healthy | 191.46 | — | 0.020033 | — | 210.3 |
| 2 | Faulty 0.5% | 188.12 | 1.74 | 0.019847363 | 0.93 | 68.30 |
| 3 | Faulty 1% | 185.79 | 2.96 | 0.019660566 | 1.86 | 47.58 |
| 4 | Faulty 2% | 179.94 | 6.02 | 0.019283 | 3.75 | 55.4 |
| 5 | Faulty 5% | 165.67 | 13.47 | 0.018122 | 9.54 | 55.5 |
| 6 | Faulty 10% | 148.41 | 22.49 | 0.016136 | 19.45 | 36.8 |
| 7 | Faulty 15% | 138.28 | 27.54 | 0.014197 | 29.13 | 19.7 |
| 8 | Faulty 20% | 132.73 | 30.67 | 0.012349 | 38.65 | 43.7 |
| 9 | Faulty 25% | 129.69 | 32.26 | 0.010601 | 47.09 | 50.3 |
| 10 | Faulty 30% | 128.21 | 33.04 | 0.008954 | 55.30 | 59.3 |

TABLE 9
Rₚₕₐₛₑ = 20.304876 mOhm, Magnet and Winding Temperature = 80° C.

| | | RMS of | | | % Reduction | |
|---|---|---|---|---|---|---|
| | | Phase A | % Reduction | PM Flux (Wb) | in PM Flux | Torque |
| | | Current | in RMS value | Resultant of | Resultant of | pk2pk |
| no | | (A) | of Phase A | no-load test | no-load test | (mN · m) |
| 1 | Healthy | 163.41 | — | 0.018123 | — | 44.3 |
| 2 | Faulty 0.5% | 161.14 | 1.39 | 0.017936642 | 1.03 | 44.41 |
| 3 | Faulty 1% | 159.66 | 2.29 | 0.01774942 | 2.06 | 50.62 |
| 4 | Faulty 2% | 156.11 | 4.47 | 0.017373 | 4.14 | 135.4 |
| 5 | Faulty 5% | 147.07 | 10.00 | 0.016243 | 10.38 | 53.7 |
| 6 | Faulty 10% | 137.07 | 16.12 | 0.014399 | 20.55 | 28.2 |
| 7 | Faulty 15% | 131.33 | 19.68 | 0.012636 | 30.28 | 24.3 |
| 8 | Faulty 20% | 128.56 | 21.33 | 0.01096 | 39.52 | 48.1 |
| 9 | Faulty 25% | 126.47 | 22.61 | 0.009376 | 48.27 | 56.6 |
| 10 | Faulty 30% | 125.88 | 22.97 | 0.007885 | 56.49 | 62.0 |

TABLE 10
Rₚₕₐₛₑ = 21.1323 mOhm, Magnet and Winding Temperature = 120° C.

| | | RMS of | | | % Reduction | |
|---|---|---|---|---|---|---|
| | | Phase A | % Reduction | PM Flux (Wb) | in PM Flux | Torque |
| | | Current | in RMS value | Resultant of | Resultant of | pk2pk |
| no | | (A) | of Phase A | no-load test | no-load test | (mN · m) |
| 1 | Healthy | 152.92 | — | 0.017087 | — | 194.7 |
| 2 | Faulty 0.5% | 151.03 | 1.24 | 0.016903608 | 1.07 | 43.63 |
| 3 | Faulty 1% | 149.57 | 2.19 | 0.016720459 | 2.14 | 38.36 |
| 4 | Faulty 2% | 146.79 | 4.01 | 0.016355 | 4.28 | 46.2 |
| 5 | Faulty 5% | 140.16 | 8.34 | 0.01527 | 10.63 | 39.5 |
| 6 | Faulty 10% | 132.83 | 13.14 | 0.013518 | 20.88 | 15.3 |
| 7 | Faulty 15% | 129.13 | 15.56 | 0.011846 | 30.67 | |
| 8 | Faulty 20% | 126.35 | 17.37 | 0.010258 | 39.96 | 55.1 |
| 9 | Faulty 25% | 125.88 | 17.68 | 0.008757 | 48.75 | 62.1 |
| 10 | Faulty 30% | 125.45 | 17.96 | 0.007346 | 57.01 | 60.3 |

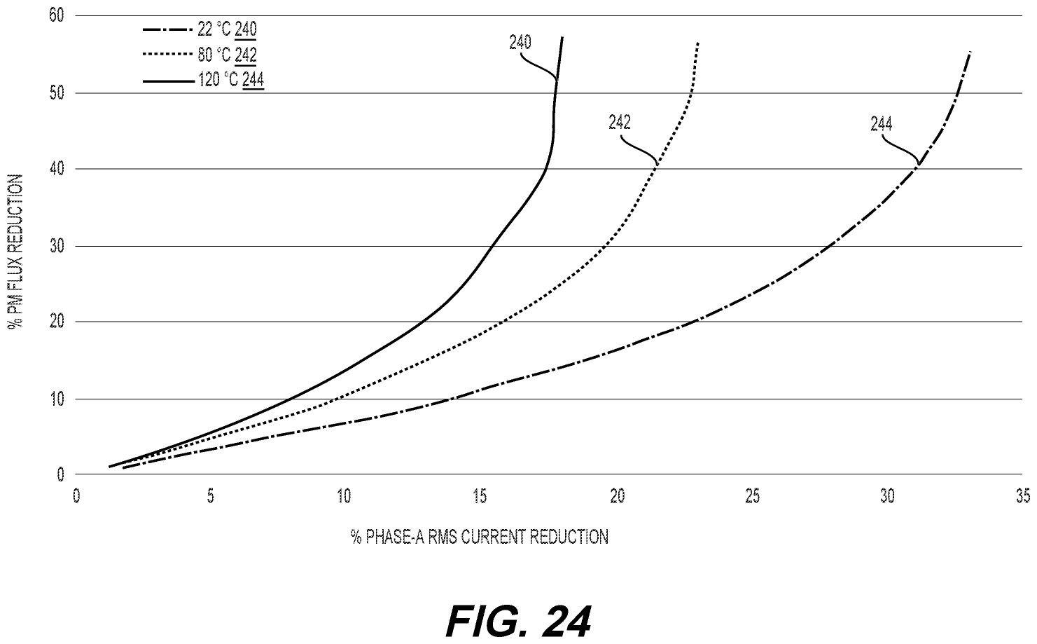

Data in the above tables 8-10 are summarized in FIG. 24, which shows a graph with plots 240, 242, 244 each representing % PM flux reduction vs. % reduction in phase A RMS current. Specifically, plot 240 shows the case for the second PMSM 26b at 22 deg. C; plot 242 shows the case for the second PMSM 26b at 80 deg. C; and plot 244 shows the case for the second PMSM 26b at 120 deg. C. Using these graphs, the PM strength after demagnetization can be obtained. Simulations can be repeated for different temperatures, and results may be stored in a lookup table. Alternatively, results may be computed. For example, curve fitting may be used to determine a mathematical relationship matching the experimentally-obtained data, and that mathematical relationship may be used subsequently to calculate the PM flux. PM flux may be obtained by knowing the temperature and calculating phase current RMS. Additionally or alternatively, an artificial neural network (ANN)-based algorithm can be trained to estimate PM flux.

The present disclosure provides a method for monitoring the PM strength of a permanent magnet synchronous machine (PMSM). The method comprises: applying phase voltages to each of a plurality of motor leads of the PMSM with the PMSM at a stand-still condition; measuring current in each of the plurality of motor leads of the PMSM while applying the phase voltages thereto; and determining at least one of: flux linkage, permanent magnet (PM) strength, PM State of Health, or PM demagnetization based on a value of the current in at least one of the plurality of motor leads.

In some embodiments, the step of determining at least one of flux linkage, permanent magnet (PM) strength, PM State of Health, or PM demagnetization includes comparing the current in the at least one of the plurality of motor leads to a current value of the PMSM in a healthy condition. In some embodiments, the step of determining at least one of flux linkage, permanent magnet (PM) strength, PM State of Health, or PM demagnetization includes comparing the current in the at least one of the plurality of motor leads to a current value of the PMSM having a predetermined amount of demagnetization. In some embodiments, determining the flux linkage, permanent magnet (PM) strength, PM State of Health, or PM demagnetization is based on a flux vector angle.

In some embodiments, the method further comprises calculating root-mean-square (RMS) value of the current in the at least one of the plurality of motor leads; and the value of the current in the at least one of the plurality of motor leads is the RMS value of the current in the at least one of the plurality of motor leads.

In some embodiments, applying phase voltages to each of the plurality of motor leads of the PMSM causes the PMSM to generate zero average torque.

In some embodiments, the phase voltages are defined by:

vₐₛ^{*}(θ, ωt)=Vₘ·cos (θ)·sin (ωt)

v_{bs}^{*}(θ, ωt)=Vₘ·cos (θ−2π/3)·sin (ωt)

v_{cs}^{*}(θ, ωt)=Vₘ·cos (θ−2π/3)·sin (ωt)

In some embodiments, determining the at least one of flux linkage, permanent magnet (PM) strength, PM State of Health, or PM demagnetization based on the value of the current in the at least one of the plurality of motor leads further comprises comparing the value of the current to each of a plurality of predetermined values corresponding to different amounts of demagnetization.

In some embodiments, determining the at least one of flux linkage, permanent magnet (PM) strength, PM State of Health, or PM demagnetization includes determining a demagnetization of only a single pole of the PMSM. In some embodiments, determining the at least one of flux linkage, permanent magnet (PM) strength, PM State of Health, or PM demagnetization includes determining a demagnetization of two or more poles of the PMSM.

In some embodiments, determining the least one of flux linkage, permanent magnet (PM) strength, PM State of Health, or PM demagnetization includes determining a reduction in PM strength based on a reduction of the current in the at least one of the plurality of motor leads. In some embodiments, determining the reduction in PM strength based on the reduction of the current in the at least one of the plurality of motor leads includes using a lookup table to determine the reduction in PM strength. In some embodiments, determining the reduction in PM strength based on the reduction of the current in the at least one of the plurality of motor leads includes using a mathematical model to calculate the reduction in PM strength. In some embodiments, determining the reduction in PM strength based on the reduction of the current in the at least one of the plurality of motor leads includes using an artificial neural network to determine the reduction in PM strength. 100861 The present disclosure provides a system 10 for monitoring a permanent magnet synchronous machine (PMSM) 26. The system 10 comprises an inverter 20 configured to apply phase voltages to each of a plurality of motor leads 24 of the PMSM 26 with the PMSM 26 at a stand-still condition. The system 10 also comprises one or more current sensors 28 configured to measure current in each of the plurality of motor leads while applying the phase voltages thereto. The system 10 also comprises a controller 30 configured to determine at least one of flux linkage, permanent magnet (PM) strength, PM State of Health, or PM demagnetization of the PMSM 26 based on a value of the current in at least one of the plurality of motor leads 28.

The provided method provides several advantages over existing online and offline methods. There is no need of extra hardware, motor disassembly or during the diagnosis. In addition, the provided method is not affected by load variations, mechanical problems and other motor parameters as it is performed with the PMSM at standstill.

The system, methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or alternatively, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a machine readable medium.

The computer executable code may be created using a structured programming language such as C, an object oriented programming language such as C++, or any other high-level or low-level programming language (including assembly languages, hardware description languages, and database programming languages and technologies) that may be stored, compiled or interpreted to run on one of the above devices as well as heterogeneous combinations of processors processor architectures, or combinations of different hardware and software, or any other machine capable of executing program instructions.

Thus, in one aspect, each method described above and combinations thereof may be embodied in computer executable code that, when executing on one or more computing devices performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

The foregoing description is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A method for monitoring a permanent magnet synchronous machine (PMSM) comprising:
applying phase voltages to each of a plurality of motor leads of the PMSM with the PMSM at a stand-still condition, wherein applying the phase voltages to each of the plurality of motor leads of the PMSM causes the PMSM to generate zero average torque;
measuring current in each of the plurality of motor leads while applying the phase voltages thereto; and
determining at least one of flux linkage, permanent magnet (PM) strength, PM State of Health, or PM demagnetization based on a value of the current in at least one of the plurality of motor leads.

2. The method of claim 1, wherein determining the at least one of flux linkage, permanent magnet (PM) strength, PM State of Health, or PM demagnetization includes comparing the current in the at least one of the plurality of motor leads to a current value of the PMSM in a healthy condition.

3. The method of claim 1, wherein determining the at least one of flux linkage, permanent magnet (PM) strength, PM State of Health, or PM demagnetization includes comparing the current in the at least one of the plurality of motor leads to a current value of the PMSM having a predetermined amount of demagnetization.

4. The method of claim 1, wherein determining the at least one of flux linkage, permanent magnet (PM) strength, PM State of Health, or PM demagnetization is based on a flux vector angle.

5. The method of claim 1, further comprising calculating a root-mean-square (RMS) value of the current in the at least one of the plurality of motor leads; and
wherein the value of the current in the at least one of the plurality of motor leads is the RMS value of the current in the at least one of the plurality of motor leads.

6. (canceled)

7. The method of claim 1, wherein the phase voltages are defined by:
vₐₛ^{*}(θ, ωt)=Vₘ·cos (θ)·sin (ωt)
v_{bs}^{*}(θ, ωt)=Vₘ·cos (θ−2π/3)·sin (ωt)
v_{cs}^{*}(θ, ωt)=Vₘ·cos (θ−2π/3)·sin (ωt),
where Vₘ, ω, and θ are voltage amplitude, excitation frequency, and flux vector angle, respectively.

8. The method of claim 1, wherein determining the at least one of flux linkage, permanent magnet (PM) strength, PM State of Health, or PM demagnetization based on the value of the current in the at least one of the plurality of motor leads further comprises comparing the value of the current to each of a plurality of predetermined values corresponding to different amounts of demagnetization.

9. The method of claim 1, wherein determining the at least one of flux linkage, permanent magnet (PM) strength, PM State of Health, or PM demagnetization includes determining a demagnetization of only a single pole of the PMSM.

10. The method of claim 1, wherein determining the at least one of flux linkage, permanent magnet (PM) strength, PM State of Health, or PM demagnetization includes determining a demagnetization of two or more poles of the PMSM.

11. The method of claim 1, wherein determining the at least one of flux linkage, permanent magnet (PM) strength, PM State of Health, or PM demagnetization includes determining a reduction in PM strength based on a reduction of the current in the at least one of the plurality of motor leads.

12. The method of claim 11, wherein determining the reduction in PM strength based on the reduction of the current in the at least one of the plurality of motor leads includes using a lookup table to determine the reduction in PM strength.

13. The method of claim 11, wherein determining the reduction in PM strength based on the reduction of the current in the at least one of the plurality of motor leads includes using a mathematical model to calculate the reduction in PM strength.

14. The method of claim 11, wherein determining the reduction in PM strength based on the reduction of the current in the at least one of the plurality of motor leads includes using an artificial neural network to determine the reduction in PM strength.

15. A system for monitoring a permanent magnet synchronous machine (PMSM) comprising:
an inverter configured to apply phase voltages to each of a plurality of motor leads of the PMSM with the PMSM at a stand-still condition, the phase voltages causing the PMSM to generate zero average torque;
one or more current sensors configured to measure current in each of the plurality of motor leads while applying the phase voltages thereto; and
a controller configured to determine at least one of flux linkage, permanent magnet (PM) strength, PM State of Health, or PM demagnetization of the PMSM based on a value of the current in at least one of the plurality of motor leads.

16. The system of claim 15, wherein determining the at least one of flux linkage, permanent magnet (PM) strength, PM State of Health, or PM demagnetization is based on a flux vector angle.

17. The system of claim 15, wherein the phase voltages are defined by:
vₐₛ^{*}(θ, ωt)=Vₘ·cos (θ)·sin (ωt),
v_{bs}^{*}(θ, ωt)=Vₘ·cos (θ−2π/3)·sin (ωt),
v_{cs}^{*}(θ, ωt)=Vₘ·cos (θ−2π/3)·sin (ωt),
where Vₘ, ω, and θ are voltage amplitude, excitation frequency, and flux vector angle, respectively.

18. The system of claim 15, wherein determining the at least one of flux linkage, permanent magnet (PM) strength, PM State of Health, or PM demagnetization includes determining a demagnetization of only a single pole of the PMSM.

19. The system of claim 15, wherein determining the at least one of flux linkage, permanent magnet (PM) strength, PM State of Health, or PM demagnetization includes determining a demagnetization of two or more poles of the PMSM.

20. The system of claim 15, wherein determining the at least one of flux linkage, permanent magnet (PM) strength, PM State of Health, or PM demagnetization includes determining a reduction in PM strength based on a reduction of the current in the at least one of the plurality of motor leads.
